(19) United States
(12) Patent Application Publication
(10) Pub. No.: US 2026/0155624 A1
(43) Pub. Date: Jun. 4, 2026

(54) EXTERNALLY MODULATED VERTICAL-CAVITY SURFACE-EMITTING LASER (VCSEL) WITH INTEGRATED GRAPHENE-BASED ELECTROABSORPTION LAYER

(71) Applicant: II-VI Delaware, Inc., Wilmington, DE (US)

(72) Inventors: Christopher Kocot, Wilmington, DE (US); Hamish Carr Delgado, Wilmington, DE (US); Anna Tatarczak, Mountain View, CA (US); Julie Eng, Wilmington, DE (US); Giovanni Barbarossa, Wilmington, DE (US); Stephen Nelson, Wilmington, DE (US)

(21) Appl. No.: 19/408,034

(22) Filed: Dec. 3, 2025

Related U.S. Application Data
(60) Provisional application No. 63/728,100, filed on Dec. 4, 2024.
(60) Provisional application No. 63/874,923, filed on Sep. 3, 2025.

(51) Int. Cl. H01S 5/026; H01S 5/11; H01S 5/183

(52) U.S. Cl. CPC H01S 5/0265; H01S 5/11; H01S 5/18361

(57) ABSTRACT

An example optical device may have a surface-emitting laser structure that includes an active region configured to generate output light, a first distributed Bragg reflector (DBR) disposed below the active region, a second distributed Bragg reflector (DBR) disposed above the active region, a modulation structure that includes electroabsorption material, configured to modulate the output light in response to an applied bias, wherein the modulation structure is disposed within or adjacent to at least one of the first DBR and the second DBR. The electroabsorption material may include graphene or graphene-based composite material. An example method for modulating the output light may include generating a continuous-wave (CW) light in the active region, and then modulating the CW light by the modulation structure, via a bias-dependent absorption provided by the electroabsorption material.

### CLAIM OF PRIORITY

This patent application claims priority to and claims benefit from U.S. Provisional Patent Application Ser. No. 63/728,100, filed on Dec. 4, 2024, and U.S. Provisional Patent Application Ser. No. 63/874,923, filed on Sep. 3, 2025. Each of the above identified applications is hereby incorporated herein by reference in its entirety.

### TECHNICAL FIELD

Aspects of the present disclosure relate to optical communication solutions. More specifically, certain implementations of the present disclosure relate to methods and systems for implementing and utilizing externally modulated vertical-cavity surface-emitting laser (VCSEL) with integrated graphene-based electroabsorption layer.

### BACKGROUND

Limitations and disadvantages of conventional solutions for optical communications, and in particular for modulating laser emitting structures, such as vertically emitting laser structures, will become apparent to one of skill in the art, through comparison of such systems with some aspects of the present disclosure as set forth in the remainder of the present application with reference to the drawings.

### BRIEF SUMMARY

System and methods are provided for an externally modulated vertical-cavity surface-emitting laser (VCSEL) with integrated graphene-based electroabsorption layer, substantially as shown in and/or described in connection with at least one of the figures, as set forth more completely in the claims.

These and other advantages, aspects and novel features of the present disclosure, as well as details of an illustrated embodiment thereof, will be more fully understood from the following description and drawings.

### BRIEF DESCRIPTION OF THE DRAWINGS

FIG. 1 illustrates an example externally modulated top-emitter vertical-cavity surface-emitting laser (VCSEL) with an integrated graphene-based electroabsorption layer, in accordance with various example implementations of this disclosure.

FIGS. 2A, 2B and 2C illustrate an example epitaxial structure growth for an externally modulated top-emitter vertical-cavity surface-emitting laser (VCSEL), in accordance with various example implementations of this disclosure.

FIG. 3 illustrates another example externally modulated bottom-emitter vertical-cavity surface-emitting laser (VCSEL) with an integrated graphene-based electroabsorption layer, in accordance with various example implementations of this disclosure.

FIGS. 4A, 4B and 4C illustrate an example epitaxial structure growth for an externally modulated bottom-emitter vertical-cavity surface-emitting laser (VCSEL), in accordance with various example implementations of this disclosure.

FIG. 5 illustrates another example externally modulated top-emitter vertical-cavity surface-emitting laser (VCSEL) with an integrated graphene-based electroabsorption layer, in accordance with various example implementations of this disclosure.

FIG. 6 illustrates another example externally modulated vertical-cavity surface-emitting laser (VCSEL) with an integrated graphene-based electroabsorption layer, in accordance with various example implementations of this disclosure.

FIG. 7 illustrates another example externally modulated vertical-cavity surface-emitting laser (VCSEL) with an integrated graphene-based electroabsorption layer, in accordance with various example implementations of this disclosure.

FIG. 8 illustrates another example externally modulated vertical-cavity surface-emitting laser (VCSEL) with an integrated graphene-based electroabsorption layer and an optical resonator, in accordance with various example implementations of this disclosure

### DETAILED DESCRIPTION

The present disclosure relates to optical communication systems, and specifically to new and improved laser emitting structures with enhanced performance. In particular, various embodiments described herein are directed to vertical cavity surface-emitting lasers (VCSELs) with enhanced bandwidth capabilities using external modulation. In this regard, directly modulated lasers (DMLs) may be nearing their bandwidth limitations, which hinders their application in next-generation high-speed optical communication systems. For example, conventional VCSELs may be limited in modulation speed due to carrier recombination dynamics and parasitic capacitance within the active region. To enhance data rates, external modulators are often employed. However, such systems may increase manufacturing complexity, alignment requirements, and overall cost. In this regard, conventional high-speed optical communication systems with externally-modulated, edge-emitting lasers may lack the cost efficiency and ease of testing inherent to VCSELs.

Combining the advantages of structures such as VCSELs with an efficient high-bandwidth, external modulation mechanism as disclosed herein may address the current limitations while retaining the benefits of vertical laser structures. In accordance with this disclosure, this may be done by incorporating into the structures modulation layers that provide and/or facilitate external modulation. In particular, various embodiments based on this disclosure relate to optoelectronic devices, such as VCSELs, that incorporate a thin layer of electroabsorption material to enable providing or supporting external modulation. As noted, conventional VCSELs are widely used in communication systems because of their low cost, ease of fabrication, and compatibility with wafer-level testing. However, these devices generally rely on direct current modulation, which may limit achievable data rates, increase drive voltages, and introduce thermal inefficiencies. The present disclosure addresses such shortcomings by introducing an externally modulated laser emitting structures, such as externally modulated VCSELs.

In this regard, an externally modulated VCSEL implemented in accordance with this disclosure may integrate a thin electroabsorption material, such as graphene. Such electroabsorption layer (e.g., graphene-based electroabsorption layer) may be disposed on the top or bottom surface of the structure, or may be positioned adjacent to or embedded within one of the distributed Bragg reflector (DBR) stacks. The use of electroabsorption material such as graphene may allow, due to its atomic-scale thickness, exceptional carrier mobility, and tunable electroabsorption through electric field control, for achieving high-speed, low-power optical modulation within the VCSEL cavity.

The layer of electroabsorption material may function as a modulation layer. By applying an electric field to this material through an ohmic contact, its absorption properties may be dynamically controlled, enabling modulation of the laser output while allowing the continuous-wave (CW) operation of the VCSEL to remain independently biased. In this regard, by applying an independent bias to the graphene-based electroabsorption layer, its absorption coefficient may be modulated, dynamically altering the output light intensity or wavelength. Such independent control allows for separating the modulation process from the CW generation of the VCSEL, thus providing higher speed and improved efficiency. In this regard, the VCSEL structure maintains separate biasing for lasing and modulation functions, enabling high-speed operation with low power consumption.

In some instances, the electroabsorption layer further comprises additional two-dimensional materials, such as molybdenum disulfide (MoS₂) or tungsten diselenide (WSe₂), to tailor the optical response.

The configuration proposed herein is adaptable for both top-emitting and bottom-emitting architectures and may be realized using standard epitaxial growth followed by graphene deposition techniques such as atomic layer deposition (ALD), chemical vapor deposition (CVD), or vapor phase epitaxy (VPE). The epitaxial growth may comprise fabricating an epitaxial laser structure, such as using molecular beam epitaxy (MBE) or metal-organic chemical vapor deposition (MOCVD). The proposed structures combine scalability, energy efficiency, and superior modulation performance suitable for optical communication, sensing, and LiDAR systems.

As noted, graphene may be used as electroabsorption material. In this regard, use of graphene as electroabsorption material may be advantageous because of its atomic-scale thickness, excellent electroabsorption response, and compatibility with thin-film deposition techniques. Incorporating graphene within the structures enables high-speed modulation with a minimal device footprint. An important design goal is achieving low drive voltage. This may be realized by one or more of positioning the graphene layer close to the active region, coupling the graphene layer with a resonant cavity such as a high-contrast grating, doping the graphene layer to shift its Fermi level, and including a dielectric layer adjacent to the graphene. Another advantage is that graphene may be integrated into the VCSEL structure, to enable external modulation, without disturbing the epitaxial laser growth process or requiring external optical components.

The graphene-based modulation layer may be incorporated in multiple configurations. In one example arrangement, the graphene layer is deposited externally on the top or bottom of the VCSEL structure. For a bottom-emitting VCSEL, the substrate may have an anti-reflection (AR) coating that may comprise sequential layers of indium tin oxide (ITO), a dielectric layer optimized for RC constant, bandwidth, and voltage swing, graphene, and a passivation layer. For a top-emitting VCSEL, the corresponding stack may comprise layers of ITO, dielectric, graphene, and passivation deposited above the top DBR. In either configuration, alternative transparent conductive materials may replace ITO. In another example arrangement, a thin graphene layer may be positioned within or adjacent to the DBR stack and near the active region of the VCSEL. The thin graphene layer may comprise a few atomic thick sub-layers of graphene. Placement in such a high-field region ensures strong interaction with the optical mode, yielding a high extinction ratio (ER) for modulation while maintaining compact device geometry.

The graphene-based modulation layer may enable independent biasing. In this regard, the modulation layer may be controlled independently of the VCSEL laser operation. A separate bias applied through an ohmic contact may dynamically tune the absorption of the graphene layer, while independent electrical contacts maintain biasing of the VCSEL active region. This architecture allows the CW laser operation and external modulation to function without interference, supporting higher performance and greater design flexibility.

In one example embodiment, a VCSEL structure includes an active region sandwiched between top and bottom DBR stacks, and a graphene-based electroabsorption layer, comprising one to several atomic layers, is integrated either on the top surface, bottom surface, or within one of the DBR stacks. The graphene-based electroabsorption layer enables electroabsorption modulation of the laser output through an applied bias across ohmic contacts. The VCSEL operation is controlled through a separate bias, thereby decoupling lasing from modulation.

In one example embodiment, a VCSEL structure incorporates a graphene-based electroabsorption layer located adjacent to the substrate. The active region is positioned between upper and lower DBR stacks. Independent bias contacts provide separate electrical connections for the graphene modulation layer and VCSEL laser operation, respectively.

In one example embodiment, a top-emitting VCSEL structure includes a graphene-based electroabsorption layer that is deposited above the top DBR, overlaid with a transparent conductive oxide such as ITO and protected by a passivation layer.

In one example embodiment, a bottom-emitting VCSEL structure includes a graphene-based electroabsorption layer that is integrated beneath the bottom DBR or directly on a substrate featuring AR coatings and dielectric films optimized for RC time constant and optical impedance matching.

In various example embodiments, low drive voltage and high extinction ratio (ER) modulation may be achieved by positioning the graphene-based electroabsorption layer in a high-field region near the active cavity or by optimizing resonant optical coupling through structures such as high-contrast gratings or photonic crystals—that is, an optical resonator layer. Further, selective doping or electrostatic gating may be used to tune the Fermi level of the graphene for enhanced modulation efficiency. The overall design according to the present disclosure is compatible with semiconductor wafer-scale manufacturing, facilitating cost-effective and scalable production. In this regard, the disclosed structures are compatible with wafer-level testing and scalable fabrication processes.

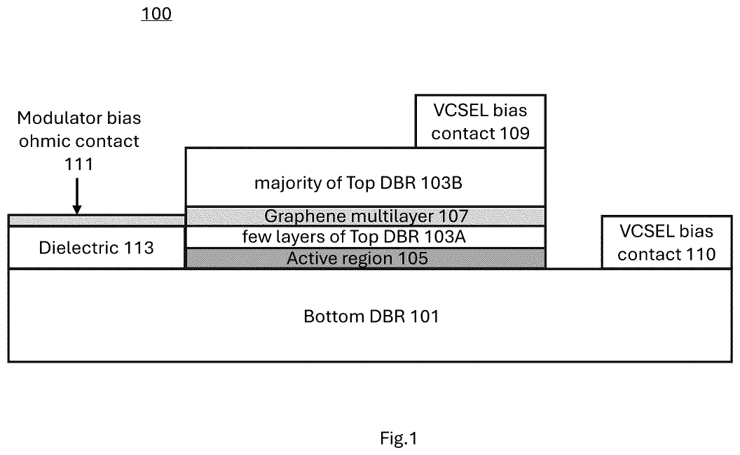

Example embodiments incorporating externally modulated VCSEL structures, and features and details relating thereto, are described in more detail with respect to FIGS. 1-8.

Nonetheless, while various embodiments described herein are VCSEL based embodiments, the present disclosure is not limited to VCSELs, and also applies to other vertically emitting laser structures, such as vertical external cavity surface-emitting lasers (VECSELs) and photonic crystal surface-emitting lasers (PCSELs). Further, similar solutions as described herein—that is, where a modulation layer or structure, which may comprise electroabsorption material such as graphene, is added or incorporated to provide or facilitate external modulation separately from and independently of light generation functions—may be used in semiconductor light sources in general, and in micro-LEDs in particular.

FIG. 1 illustrates an example externally modulated top-emitter vertical-cavity surface-emitting laser (VCSEL) with an integrated graphene-based electroabsorption layer, in accordance with various example implementations of this disclosure. Shown in FIG. 1 is an externally-modulated, top-emitter VCSEL 100.

The VCSEL 100 comprises an active region 105, a bottom DBR 101, a top DBR 103A, and an electroabsorption material. The electroabsorption material may comprise a graphene multilayer 107 embedded between a first section of the top DBR 103A and a second section 103B of the top DBR 103A. The first section of the top DBR 103A may comprise only a few (e.g., 3-10) layers of the entire top DBR 103A stack. The particular number of layers (depth) of first section 103A may be determined according to a field strength at a distance (equal to the depth) from the active region 105. The proximity of the graphene multilayer 107 to the active region 105 may enable a high extinction ratio (ER) of the modulation.

In operation, a continuous-wave (CW) light may be generated in the active region 105. The CW may be modulated via the graphene multilayer 107 according to a modulation bias applied at an ohmic contact 111. The modulation bias may be independent of a VCSEL bias that may be applied to the bottom DBR 101 and/or the top DBR 103B. A dielectric 113 may separate the ohmic contact 111 from the bottom DBR 101. The graphene multilayer 107 may be placed close to the active region 105 (e.g., in a high field region) to ensure a high extinction ratio (ER) of the modulation.

The full epitaxial stack of the DBRs 101, 103A-B may be fabricated through epitaxial growth, while the graphene multilayer 107 may be deposited using atomic layer deposition (ALD) or other suitable methods.

The VCSEL 100 may be biased using a top contact 109 and/or a bottom contact 110. A method of modulating light output in the VCSEL 100 may comprise generating CW light in the active region 105 and modulating the CW light using a bias-dependent absorption mechanism provided by the thin electroabsorption material integrated into the top DBR 103A-B stack. The VCSEL 100 and the modulation layer 107 may be electrically isolated, allowing independent operation. The VCSEL 100 maintains CW operation through one bias circuit, while the modulation layer 107 varies light output based on a separate modulator bias.

Incorporating the thin graphene multilayer 107 within the top DBR 103A stack (e.g., between first section of the top DBR 103A and a second section 103B) of the VCSEL 100 enables high-speed modulation. By applying an electric field through an ohmic contact 111 to the graphene multilayer 107, the absorption properties of the graphene multilayer 107 may be dynamically adjusted, to control the modulation of the output of the laser 100. This method allows for independent control of the CW operation and the modulation process of the laser 100. Graphene's exceptional electroabsorption properties, combined with its minimal thickness, make it an ideal candidate for this application. While graphene is one example material due to its superior electroabsorption properties and thinness, other materials with similar characteristics may be used, such as transition metal dichalcogenides (TMDs). The modulation layer 107 may be applied close to the active region of the VCSEL 100, without disrupting the amplifying function of the DBR mirrors 101, 103A-B or the laser cavity 105.

To increase stability of the graphene multilayer 107 and create a suitable ohmic contact, the thickness of the graphene multilayer 107 may be approximately 20 nm. With a thickness of 20 nm, for example, the graphene multilayer 107 is thin enough that it does not affect the optical properties of the DBR structure, when the graphene multilayer 107 is in the “off” (zero bias) state. This unique characteristic enables the integration of the graphene multilayer 107 as a modulation layer 107 within the DBR stack 103A-B, positioned in close proximity to the active region 105 where the electric field is strong. As a result, the VCSEL 100 achieves high modulation performance (i.e., high extinction ratio (ER)) without compromising the reflective function of the DBR in the off state. In contrast, alternative materials would require greater thickness, which would adversely affect the DBR reflectivity and resonance characteristics in the off state. Moreover, graphene's absorption coefficient exhibits a strong dependence on the applied electric field, and its excellent thermal expansion compatibility minimizes stress-related challenges that other materials would introduce.

The design described herein is compatible with the existing VCSEL fabrication process, preserving cost-effectiveness and enabling wafer-level testing.

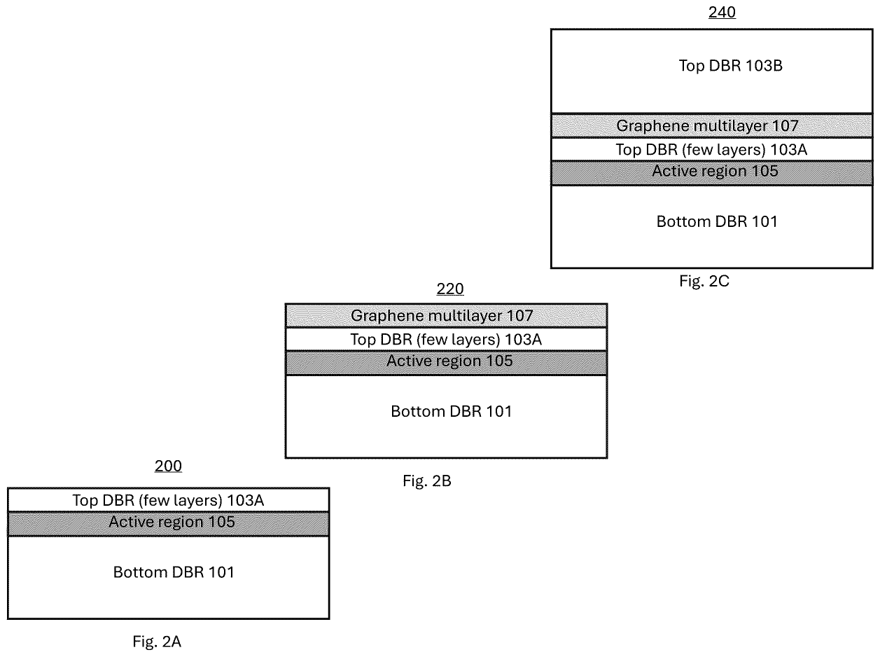

FIGS. 2A, 2B and 2C illustrate an example epitaxial structure growth for an externally modulated top-emitter vertical-cavity surface-emitting laser (VCSEL), in accordance with various example implementations of this disclosure. Shown in FIGS. 2A, 2B and 2C is an example epitaxial structure growth for the VCSEL 100 of FIG. 1.

In this regard, as shown in FIG. 2A, in a first step 200, the full bottom DBR 101 and a small portion of the top DBR 103A may be grown, such as using conventional epitaxial growth methods. As shown in FIG. 2B, in a second step 220, the graphene multilayer 107 may be then deposited, such as using ALD or other advanced deposition techniques, ensuring process compatibility. As shown in FIG. 2C, in a third step 240, the remainder of the top DBR 103B may be grown, such as using conventional epitaxial growth methods.

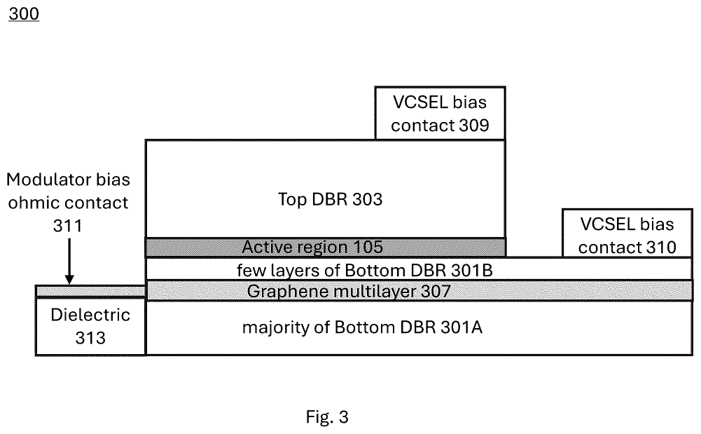

FIG. 3 illustrates another example externally modulated bottom-emitter VCSEL with an integrated graphene-based electroabsorption layer, in accordance with various example implementations of this disclosure. Shown in FIG. 3 is an externally-modulated, bottom-emitter VCSEL 300.

The VCSEL 300 comprises an active region 305, a top DBR 303, a bottom DBR 301, and an electroabsorption material. The electroabsorption material may comprise a graphene multilayer 307 embedded between a first section of bottom DBR 301B and a second section 301A of the bottom DBR. The first section of bottom DBR 301B may comprise only a few (e.g., 3-10) layers of the entire top DBR stack. The particular number of layers (depth) of first section 301B may be determined according to a field strength at a distance (equal to the depth) from the active region 305. The proximity of the graphene multilayer 307 to the active region 305 may enable a high extinction ratio (ER) of the modulation.

In operation, a CW light may be generated in the active region 305. The CW light may be modulated via the graphene multilayer 307 according to a modulation bias applied at an ohmic contact 311. The modulation bias may be independent of a VCSEL bias that may be applied to the bottom DBR 301B and/or the top DBR 303. A dielectric 313 may separate the ohmic contact 311 from the bottom DBR 301A. The graphene multilayer 307 may be placed close to the active region 305 (e.g., in a high field region) to ensure a high extinction ratio (ER) of the modulation.

The full epitaxial stack of the DBRs 303, 301A-B may be fabricated through epitaxial growth, while the graphene multilayer 307 may be deposited using ALD or other suitable methods.

The VCSEL 300 may be biased using a top contact 309 and/or a bottom contact 310. A method of modulating light output in the VCSEL 300 may comprise generating CW light in the active region 305 and modulating the CW light using a bias-dependent absorption mechanism provided by the thin electroabsorption material integrated into the top DBR stack 301A-B. The VCSEL 300 and the modulation layer 307 may be electrically isolated, allowing independent operation. The VCSEL 300 maintains CW operation through one bias circuit, while the modulation layer 307 varies light output based on a separate modulator bias.

Incorporating the thin graphene multilayer 307 within the bottom DBR stack 301A-B of the VCSEL 300 enables high-speed modulation. By applying an electric field through an ohmic contact 311 to the graphene multilayer 307, the absorption properties of the graphene multilayer 307 may be dynamically adjusted, to control the modulation of the output of laser 300. This method allows for independent control of the CW operation and the modulation process of laser 300. Graphene's exceptional electroabsorption properties, combined with its minimal thickness, make it an ideal candidate for this application. While graphene is one example material due to its superior electroabsorption properties and thinness, other materials with similar characteristics may be used, such as TMDs. The modulation layer 307 may be applied close to the active region of the VCSEL 300, without disrupting the amplifying function of the DBR mirrors 303, 301A-B or the laser cavity 305.

To increase stability of the graphene multilayer 307 and create a suitable ohmic contact, the thickness of the graphene multilayer 307 may be, for example, approximately 20 nm. With a thickness of 20 nm, for example, the graphene multilayer 307 is thin enough that it does not affect the optical properties of the DBR structure, when the graphene multilayer 307 is in the “off” (zero bias) state. This unique characteristic enables the integration of the graphene multilayer 307 as a modulation layer 307 within the DBR stack 301A-B, positioned in close proximity to the active region 305 where the electric field is strong. As a result, the VCSEL 300 achieves high modulation performance (i.e., high extinction ratio (ER)) without compromising the reflective function of DBR in the off state of the modulator. In contrast, alternative materials may require greater thickness, which may adversely affect the DBR reflectivity and resonance characteristics in the off state. Moreover, graphene's absorption coefficient exhibits a strong dependence on the applied electric field, and its excellent thermal expansion compatibility minimizes stress-related challenges that other materials would introduce.

The design is compatible with the existing VCSEL fabrication process, preserving cost-effectiveness and enabling wafer-level testing.

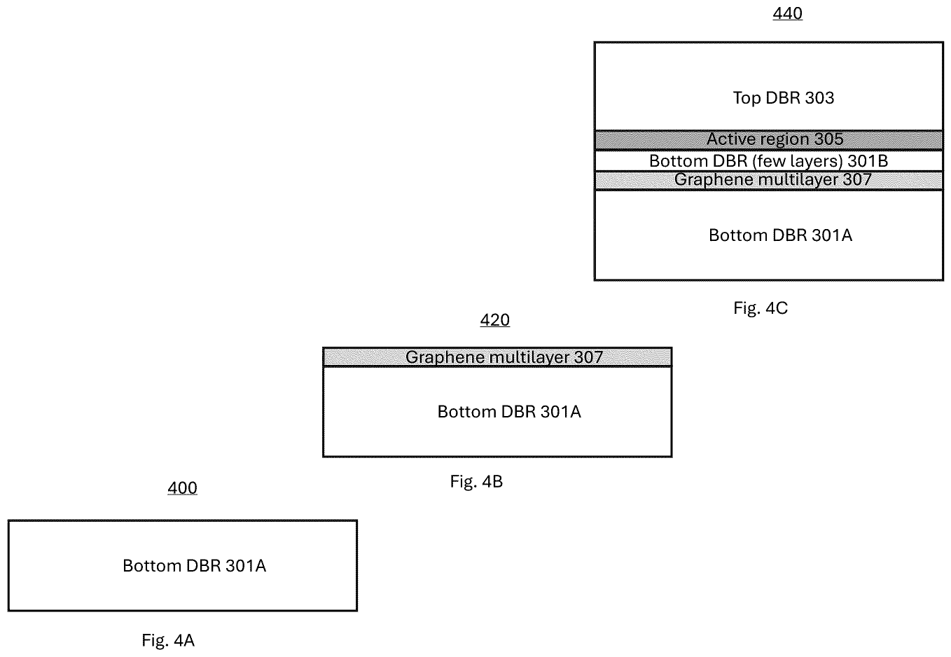

FIGS. 4A, 4B and 4C illustrate an example epitaxial structure growth for an externally modulated bottom-emitter VCSEL, in accordance with various example implementations of this disclosure. Shown in FIGS. 4A, 4B and 4C is example epitaxial structure growth for the VCSEL 300 of FIG. 3.

In this regard, as shown in FIG. 4A, in a first step 400, the majority of the bottom DBR 301A may be grown using conventional epitaxial growth methods. As shown in FIG. 4B, in a second step 420, the graphene multilayer 307 may be deposited, such as using ALD or other advanced deposition techniques, ensuring process compatibility. As shown in FIG. 4C, in a third step 440, a few layers of the bottom DBR stack 301B and the full DBR 303 may be grown, such as using conventional epitaxial growth methods.

While the various embodiments shown and described herein are VCSEL based, the disclosure is not limited to such devices, and as such electroabsorption material may be implemented in other vertically emitting laser structures, such as VECSELs and PCSELs. In this regard, unlike a VCSEL, in which two high-reflective DBRs are incorporated into the semiconductor structure to form the optical cavity, in a VECSEL one of these mirrors is placed outside the semiconductor structure. The electroabsorption material may be located in either the internal or external DBR of the VECSEL. While VCSELs rely on vertical distributed Bragg reflectors (DBRs) for light confinement, PCSELs utilize a photonic crystal structure to achieve in-plane optical confinement. The electroabsorption material may be located in the photonic crystal structure.

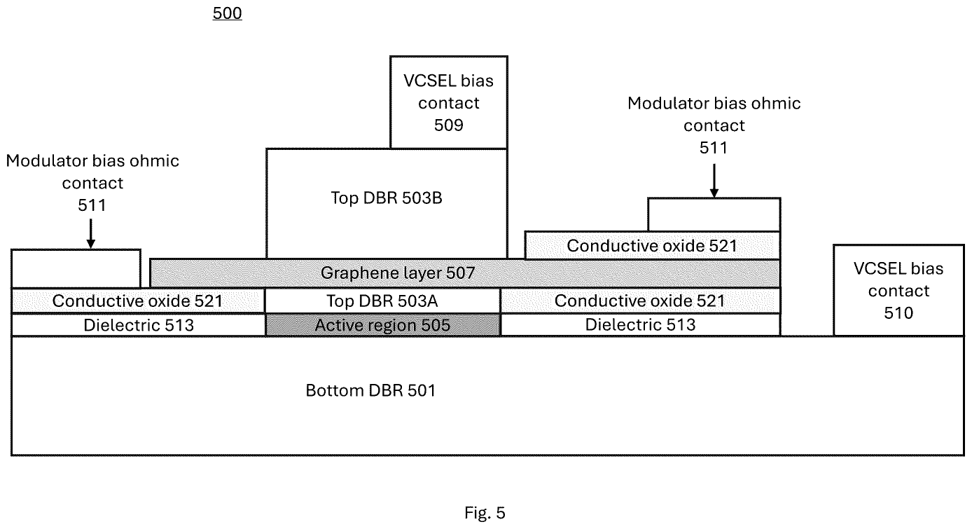

FIG. 5 illustrates another example externally modulated top-emitter VCSEL with an integrated graphene-based electroabsorption layer, in accordance with various example implementations of this disclosure. Shown in FIG. 5 is an externally-modulated, top-emitter VCSEL 500.

The VCSEL 500 may be substantially similar to the VCSEL 100, and may operate in substantially similar manner. However, the VCSEL 500 may incorporate a modified design compared to the VCSEL 100.

In this regard, as shown in FIG. 5, the VCSEL 500 comprises an active region 505, a bottom DBR 501, a top DBR 503A, and an electroabsorption material. The electroabsorption material may comprise a graphene multilayer 507 embedded between a first section of the top DBR 503A and a second section 503B of the top DBR 503A.

In addition to the first section of the top DBR 503A, the graphene multilayer 507 may be disposed on top of a conductive oxide 521 and a dielectric 513. In this regard, as shown in the example implementation illustrated in FIG. 5, two sections of each of conductive oxide 521 and a dielectric 513 may be disposed on both sides of the combination of the first section of the top DBR 503A and the active region 505. Further, on top of the graphene multilayer 507, in addition to the second section of the top DBR 503B, another layer of conductive oxide 521 may be disposed, as shown.

In operation, a CW light may be generated in the active region 505. The CW may be modulated via the graphene multilayer 507 according to a modulation bias applied at ohmic contacts 511. The modulation bias may be independent of a VCSEL bias that may be applied to the bottom DBR 501 and/or the top DBR 503B. in this regard, the VCSEL 500 may be biased using a top contact 509 and/or a bottom contact 510.

A method of modulating light output in the VCSEL 500 may comprise generating CW light in the active region 505 and modulating the CW light using a bias-dependent absorption mechanism provided by the thin electroabsorption material integrated into the top DBR 503A-B stack. The VCSEL 500 and the modulation layer 507 may be electrically isolated, allowing independent operation. The VCSEL 500 maintains CW operation through one bias circuit, while the modulation layer 507 varies light output based on a separate modulator bias.

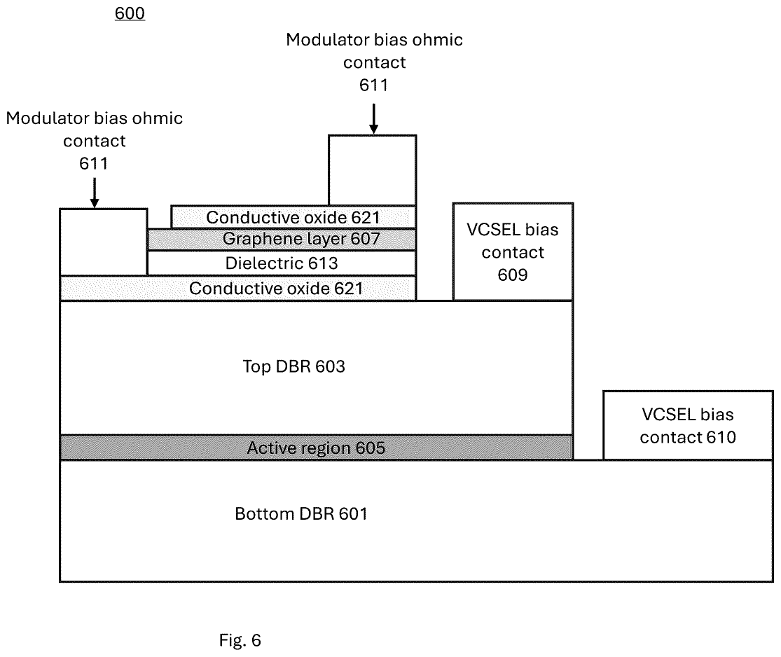

FIG. 6 illustrates another example externally modulated VCSEL with an integrated graphene-based electroabsorption layer, in accordance with various example implementations of this disclosure. Shown in FIG. 6 is an externally-modulated VCSEL 600.

As shown in FIG. 6, the VCSEL 600 comprises an active region 605, disposed between a bottom DBR 601 and a top DBR 603, and an electroabsorption material. The electroabsorption material may comprise a graphene multilayer 607. However, unlike the VCSELs described above, the graphene multilayer 607 is not disposed within the top DBR 603 or the bottom DBR 601. Rather, the graphene multilayer 607 is disposed adjacent to —namely, above or on top of—the top DBR 603, with a conductive oxide 621 and a dielectric 613 disposed between them, and with another layer of conductive oxide 621 on top of the graphene multilayer 607, as shown.

In operation, the VCSEL 600 may operate in substantially similar manner. In this regard, a CW light may be generated in the active region 605. The CW light may be modulated via the graphene multilayer 607 according to a modulation bias applied at ohmic contacts 611. The modulation bias may be independent of a VCSEL bias that may be applied to the bottom DBR 601 and/or the top DBR 603B. in this regard, the VCSEL 600 may be biased using a top contact 609 and/or a bottom contact 610.

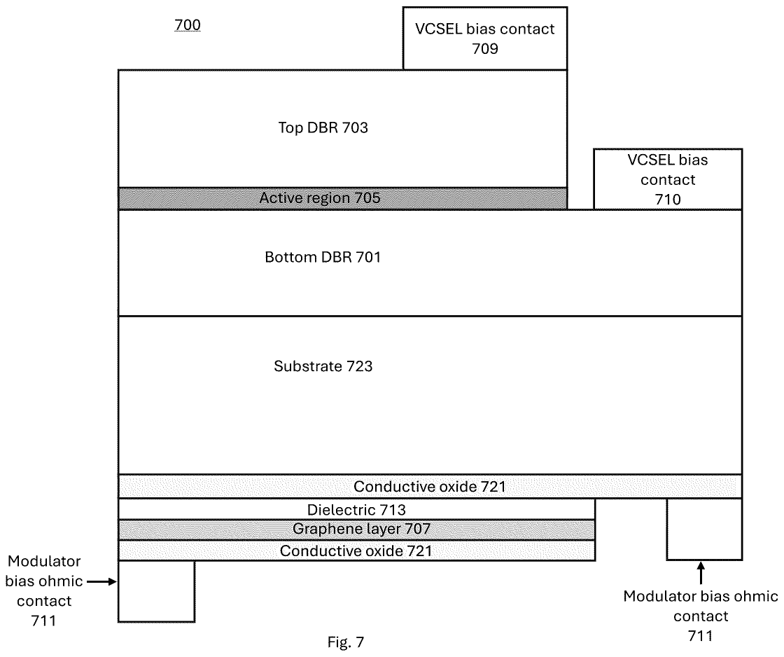

FIG. 7 illustrates another example externally modulated VCSEL with an integrated graphene-based electroabsorption layer, in accordance with various example implementations of this disclosure. Shown in FIG. 7 is an externally-modulated VCSEL 700.

As shown in FIG. 7, the VCSEL 700 comprises an active region 705, disposed between a bottom DBR 701 and a top DBR 703, and an electroabsorption material. The electroabsorption material may comprise a graphene multilayer 707. However, in the VCSEL 700, the graphene multilayer 707 is not disposed within the top DBR 703 or the bottom DBR 701. Rather, the graphene multilayer 707 is disposed adjacent to—namely, beneath or on the bottom of—the bottom DBR 701. In this regard, in the implementation used in the VCSEL 700, the bottom DBR 701 is disposed on top of a substrate 723, and the graphene multilayer 707 is disposed on the bottom of the substrate 723, with a conductive oxide 721 and a dielectric 713 disposed between the substrate 723 and the graphene multilayer 707, and with another layer of conductive oxide 721 on the bottom of the graphene multilayer 707, as shown.

In operation, the VCSEL 700 may operate in substantially similar manner. In this regard, a CW light may be generated in the active region 705. The CW light may be modulated via the graphene multilayer 707 according to a modulation bias applied at ohmic contacts 711. The modulation bias may be independent of a VCSEL bias that may be applied to the bottom DBR 701 and/or the top DBR 703B. In this regard, the VCSEL 700 may be biased using a top contact 709 and/or a bottom contact 710 (relative to the active region 705), as shown.

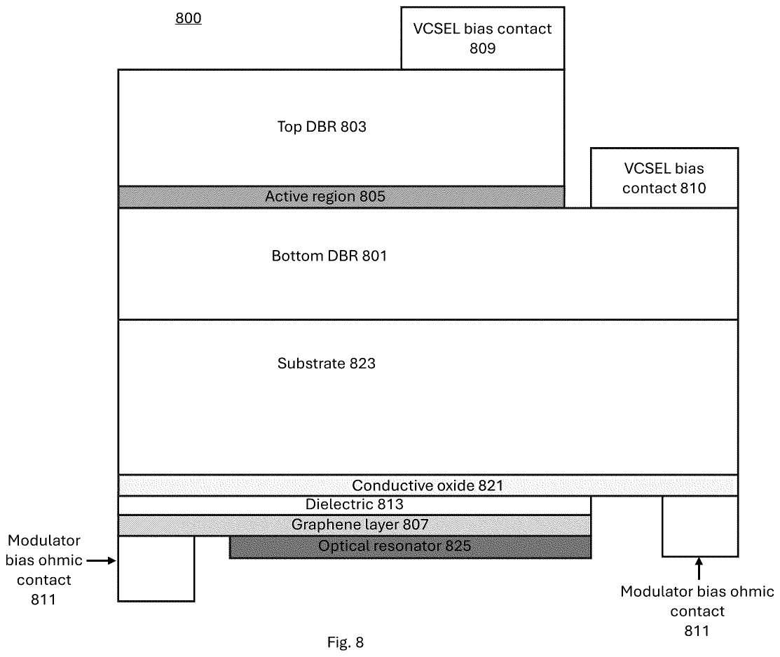

FIG. 8 illustrates another example externally modulated VCSEL with an integrated graphene-based electroabsorption layer and an optical resonator, in accordance with various example implementations of this disclosure. Shown in FIG. 8 is an externally-modulated VCSEL 800.

The VCSEL 800 may be substantially similar to the VCSEL 700, for example. In this regard, as shown in FIG. 8, the VCSEL 800 comprises an active region 805, disposed between a bottom DBR 801 and a top DBR 803, and an electroabsorption material. The electroabsorption material may comprise a graphene multilayer 807. However, in the VCSEL 800, the graphene multilayer 807 is not disposed within the top DBR 803 or the bottom DBR 801. In the example implementation used in the VCSEL 800, the bottom DBR 801 is disposed on top of a substrate 823, and the graphene multilayer 807 is disposed on the bottom of the substrate 823, with a conductive oxide 821 and a dielectric 813 disposed between the substrate 823 and the graphene multilayer 807. However, rather than using another conductive oxide at the bottom, the VCSEL 800 comprises an optical resonator 825, as shown in FIG. 8. In this regard, in the VCSEL 800, the optical resonator 825 is disposed on a bottom side of the graphene multilayer 807 and is configured to enhance optical interaction with the electro-absorption material.

The optical resonator 825 may comprise a photonic crystal or another resonant structure engineered to increase optical absorption in the electro-absorption region at or near the VCSEL emission wavelength. By providing this resonant enhancement, the optical resonator 825 improves modulation efficiency while allowing independent optimization of the electro-absorption region. In operation, the VCSEL 800 may operate in substantially similar manner to the VCSEL 700. In this regard, a CW light may be generated in the active region 805. The CW light may be modulated via the graphene multilayer 807 according to a modulation bias applied at ohmic contacts 811. The modulation bias may be independent of a VCSEL bias. In this regard, the VCSEL 800 may be biased using a top contact 809 and a bottom contact 810 (relative to the active region 805), as shown.

While in various embodiments described herein graphene is used, because of its exceptional electroabsorption properties, the disclosure is not limited to the use of graphene, and the various designs described herein allow for and/or accommodate material versatility. In this regard, in some example implementations other thin electroabsorption materials with suitable optical characteristics may be used instead of graphene. This material versatility allows adaptation to different application requirements and fabrication environments.

Designs based on the present disclosure may also allow for scalable fabrication. For example, the full VCSEL epitaxial stack may be fabricated using standard epitaxial growth techniques. The graphene or alternative electroabsorption layer may then be deposited using methods such as ALD, CVD, VPE, or other thin-film deposition techniques. This layered approach ensures that the disclosed structure remains compatible with established VCSEL manufacturing processes and cost-efficient production, while enabling wafer-level testing.

The present disclosure and the various designs based thereon described herein allow for various and flexible contact configurations. For example, in some implementations, the VCSEL may be biased using a top-contact scheme or through a combination of top and bottom contacts. This flexibility supports integration with a variety of system-level architectures and simplifies adaptation to different packaging and assembly requirements.

The present disclosure and the various designs based thereon described herein allow for emission direction flexibility. In this regard, various structures based on this disclosure may support both top-emitting and bottom-emitting VCSEL designs. This enables broad applicability across different device configurations and system architectures.

The present disclosure and the various designs based thereon described herein may provide and/or offer scalability and testing advantages. In this regard, various designs disclosed herein may be fully compatible with established VCSEL fabrication flows, ensuring scalability to mass production. Importantly, the VCSEL architecture preserves the ability to perform wafer-level testing, which is a critical advantage for cost-effective manufacturing.

As noted, while various designs described herein are directed to VCSEL based structures, the present disclosure is not limited to such structure, and solutions based on the present disclosure may apply to other vertical lasers. In this regard, although this disclosure describes VCSELs, the same principles may be extended to other vertical laser structures. Example of such other vertical laser structures include VECSELs and PCSELs. In each case, the integration of a thin electroabsorption modulation layer provides the same benefits of high-speed modulation and independent biasing.

Accordingly, solutions based on the present disclosure offer various advantages and improvements over traditional systems, including, e.g., enabling use of high-speed optical modulation beyond intrinsic VCSEL carrier limits, enabling use of low drive voltage operation achieved via optimized cavity placement and Fermi-level tuning of graphene, enabling use of independent modulation control without affecting lasing performance, allowing for fabrication compatibility with existing VCSEL manufacturing infrastructure, enabling versatility for both top-emitting and bottom-emitting architectures, and enabling extensibility to other laser platforms including VECSELs and PCSELs.

An example optical device, in accordance with this disclosure, comprises a surface-emitting laser structure that comprises an active region configured to generate output light, a first distributed Bragg reflector (DBR) disposed below the active region, a second distributed Bragg reflector (DBR) disposed above the active region, and a modulation structure comprising electroabsorption material, configured to modulate the output light in response to an applied bias, wherein the modulation structure is disposed within or adjacent to at least one of the first DBR and the second DBR.

In an example embodiment, the electroabsorption material comprises graphene or graphene-based composite material.

In an example embodiment, the modulation structure comprises a plurality of layers comprising the electroabsorption material.

In an example embodiment, the electroabsorption material is arranged in one or more atomic thick layers and positioned near the optical field maximum within a cavity in the surface-emitting laser structure.

In an example embodiment, the modulation structure is coupled to a capacitor and is configured to increase an extinction ratio (ER) of modulation.

In an example embodiment, wherein light emission operation of the surface-emitting laser structure is independently biased from the modulation structure.

In an example embodiment, the surface-emitting laser structure is biased via one or more contacts.

In an example embodiment, the surface-emitting laser structure is biased via a combination of one or more top contacts and one or more bottom contacts.

In an example embodiment, the modulation structure is independently biased via one or more ohmic contacts.

In an example embodiment, the second DBR comprises the modulation structure.

In an example embodiment, the first DBR comprises the modulation structure.

In an example embodiment, the surface-emitting laser structure is a top-emitter structure, and wherein the electroabsorption material is integrated on or within a top portion of the surface-emitting laser structure.

In an example embodiment, the surface-emitting laser structure is a bottom-emitter structure, and wherein the electroabsorption material is integrated on or within a bottom portion of the surface-emitting laser structure.

In an example embodiment, the modulation structure is coupled using a dielectric layer. The modulation structure may be coupled via doping using the dielectric layer. The doping may be configured to shift a Fermi level. The dielectric layer may comprise one or more of boron and nitrogen.

In an example embodiment, the modulation structure is coupled via a resonant cavity.

In an example embodiment, the resonant cavity comprises a photonic crystal.

In an example embodiment, the modulation structure is located in a high field region of the surface-emitting laser structure.

In an example embodiment, the surface-emitting laser structure further comprises an optical resonator configured for optimizing resonant optical coupling.

In an example embodiment, at least a portion of the surface-emitting laser structure is fabricated via epitaxial growth.

In an example embodiment, the modulation structure is deposited via atomic layer deposition (ALD), chemical vapor deposition (CVD), or vapor phase epitaxy (VPE).

In an example embodiment, the surface-emitting laser structure comprises a VCSEL based structure.

An example method, in accordance with this disclosure, for modulating light output in a VCSEL, comprises generating a CW light in an active region in the VCSEL, and modulating the CW light via a bias-dependent absorption provided by an electroabsorption material integrated within or adjacent to a distributed Bragg reflector (DBR) stack in the VCSEL.

In an example embodiment, the method further comprises biasing the VCSEL independently from the electroabsorption material.

In an example embodiment, the method further comprises modulating the CW light via a bias-dependent absorption provided by an electroabsorption material independently via one or more ohmic contacts.

In an example embodiment, the electroabsorption material comprises one or more layers of graphene or graphene-based composite material.

An example optical device, in accordance with this disclosure, comprises a semiconductor light source configured to generate output light, wherein the semiconductor light source comprises a modulation structure comprising electroabsorption material, and wherein the modulation structure is configured to modulate the output light via a bias-dependent absorption provided by the electroabsorption material. The modulation structure is disposed within or adjacent to at least one component of the semiconductor light source.

In an example embodiment, the electroabsorption material comprises graphene or graphene-based composite material.

In an example embodiment, the semiconductor light source comprises a micro light-emitting diode (micro-LED).

In an example embodiment, the semiconductor light source comprises a vertical external cavity surface emitting laser (VECSEL).

In an example embodiment, the semiconductor light source comprises a photonic crestal surface emitting laser (PCSEL).

As utilized herein, “and/or” means any one or more of the items in the list joined by “and/or”. As an example, “x and/or y” means any element of the three-element set {(x), (y), (x, y)}. In other words, “x and/or y” means “one or both of x and y.” As another example, “x, y, and/or z” means any element of the seven-element set {(x), (y), (z), (x, y), (x, z), (y, z), (x, y, z)}. In other words, “x, y and/or z” means “one or more of x, y, and z.” As utilized herein, the term “exemplary” means serving as a non-limiting example, instance, or illustration. As utilized herein, the terms “for example” and “e.g.” set off lists of one or more non-limiting examples, instances, or illustrations.

As utilized herein the terms “circuits” and “circuitry” refer to physical electronic components (e.g., hardware), and any software and/or firmware (“code”) that may configure the hardware, be executed by the hardware, and or otherwise be associated with the hardware. As used herein, for example, a particular processor and memory (e.g., a volatile or non-volatile memory device, a general computer-readable medium, etc.) may comprise a first “circuit” when executing a first one or more lines of code and may comprise a second “circuit” when executing a second one or more lines of code. Additionally, a circuit may comprise analog and/or digital circuitry. Such circuitry may, for example, operate on analog and/or digital signals. It should be understood that a circuit may be in a single device or chip, on a single motherboard, in a single chassis, in a plurality of enclosures at a single geographical location, in a plurality of enclosures distributed over a plurality of geographical locations, etc. Similarly, the term “module” may, for example, refer to a physical electronic component (e.g., hardware) and any software and/or firmware (“code”) that may configure the hardware, be executed by the hardware, and or otherwise be associated with the hardware.

As utilized herein, circuitry or module is “operable” to perform a function whenever the circuitry or module comprises the necessary hardware and code (if any is necessary) to perform the function, regardless of whether performance of the function is disabled or not enabled (e.g., by a user-configurable setting, factory trim, etc.).

Other embodiments of the invention may provide a non-transitory computer readable medium and/or storage medium, and/or a non-transitory machine readable medium and/or storage medium, having stored thereon, a machine code and/or a computer program having at least one code section executable by a machine and/or a computer, thereby causing the machine and/or computer to perform the processes as described herein.

Accordingly, various embodiments in accordance with the present invention may be realized in hardware, software, or a combination of hardware and software. The present invention may be realized in a centralized fashion in at least one computing system, or in a distributed fashion where different elements are spread across several interconnected computing systems. Any kind of computing system or other apparatus adapted for carrying out the methods described herein is suited. A typical implementation may comprise one or more application specific integrated circuit (ASIC), one or more field programmable gate array (FPGA), and/or one or more processor (e.g., x86, x64, ARM, PIC, and/or any other suitable processor architecture) and associated supporting circuitry (e.g., storage, DRAM, FLASH, bus interface circuits, etc.). Each discrete ASIC, FPGA, Processor, or other circuit may be referred to as “chip,” and multiple such circuits may be referred to as a “chipset.” Another implementation may comprise a non-transitory machine-readable (e.g., computer readable) medium (e.g., FLASH drive, optical disk, magnetic storage disk, or the like) having stored thereon one or more lines of code that, when executed by a machine, cause the machine to perform processes as described in this disclosure. Another implementation may comprise a non-transitory machine-readable (e.g., computer readable) medium (e.g., FLASH drive, optical disk, magnetic storage disk, or the like) having stored thereon one or more lines of code that, when executed by a machine, cause the machine to be configured (e.g., to load software and/or firmware into its circuits) to operate as a system described in this disclosure.

Various embodiments in accordance with the present invention may also be embedded in a computer program product, which comprises all the features enabling the implementation of the methods described herein, and which when loaded in a computer system is able to carry out these methods. Computer program in the present context means any expression, in any language, code or notation, of a set of instructions intended to cause a system having an information processing capability to perform a particular function either directly or after either or both of the following: a) conversion to another language, code or notation; b) reproduction in a different material form.

While the present methods and/or systems have been described with reference to certain implementations, it will be understood by those skilled in the art that various changes may be made and equivalents may be substituted without departing from the scope of the present method and/or system. In addition, many modifications may be made to adapt a particular situation or material to the teachings of the present disclosure without departing from its scope. Therefore, it is intended that the present methods and/or systems are not limited to the particular implementations disclosed, but that the present method and/or system will include all implementations falling within the scope of the appended claims.

What is claimed is:

1. An optical device, comprising:
a surface-emitting laser structure that comprises:
an active region configured to generate output light;
a first distributed Bragg reflector (DBR) disposed below the active region;
a second distributed Bragg reflector (DBR) disposed above the active region; and
a modulation structure comprising electroabsorption material, configured to modulate the output light in response to an applied bias, wherein the modulation structure is disposed within or adjacent to at least one of the first DBR and the second DBR.

2. The optical device of claim 1, wherein the electroabsorption material comprises graphene or graphene-based composite material.

3. The optical device of claim 1, wherein the modulation structure comprises a plurality of layers comprising the electroabsorption material.

4. The optical device of claim 1, wherein the electroabsorption material is arranged in one or more atomic thick layers and positioned near the optical field maximum within a cavity in the surface-emitting laser structure.

5. The optical device of claim 1, wherein the modulation structure is coupled to a capacitor and is configured to increase an extinction ratio (ER) of modulation.

6. The optical device of claim 1, wherein light emission operation of the surface-emitting laser structure is independently biased from the modulation structure.

7. The optical device of claim 1, wherein the surface-emitting laser structure is biased via one or more contacts.

8. The optical device of claim 7, wherein the surface-emitting laser structure is biased via a combination of one or more top contacts and one or more bottom contacts.

9. The optical device of claim 1, wherein the modulation structure is independently biased via one or more ohmic contacts.

10. The optical device of claim 1, wherein the second DBR comprises the modulation structure.

11. The optical device of claim 1, wherein the first DBR comprises the modulation structure.

12. The optical device of claim 1, wherein the surface-emitting laser structure is a top-emitter structure, and wherein the electroabsorption material is integrated on or within a top portion of the surface-emitting laser structure.

13. The optical device of claim 1, wherein the surface-emitting laser structure is a bottom-emitter structure, and wherein the electroabsorption material is integrated on or within a bottom portion of the surface-emitting laser structure.

14. The optical device of claim 1, wherein the modulation structure is coupled using a dielectric layer.

15. The optical device of claim 1, wherein the modulation structure is coupled via a resonant cavity.

16. The optical device of claim 15, wherein the resonant cavity comprises a photonic crystal.

17. The optical device of claim 1, wherein the modulation structure is located in a high field region of the surface-emitting laser structure.

18. The optical device of claim 1, wherein the surface-emitting laser structure further comprises an optical resonator configured for optimizing resonant optical coupling.

19. The optical device of claim 1, wherein at least a portion of the surface-emitting laser structure is fabricated via epitaxial growth.

20. The optical device of claim 1, wherein the modulation structure is deposited via atomic layer deposition (ALD), chemical vapor deposition (CVD), or vapor phase epitaxy (VPE).

21. The optical device of claim 1, wherein the surface-emitting laser structure comprises a vertical cavity surface-emitting laser (VCSEL) based structure.

22. A method of modulating light output in a vertical cavity surface-emitting laser (VCSEL), comprising:
generating a continuous-wave (CW) light in an active region in the VCSEL; and
modulating the CW light via a bias-dependent absorption provided by an electroabsorption material integrated within or adjacent to a distributed Bragg reflector (DBR) stack in the VCSEL.

23. The method of claim 22, further comprising biasing the VCSEL independently from the electroabsorption material.

24. The method of claim 22, further comprising modulating the CW light via a bias-dependent absorption provided by an electroabsorption material independently via one or more ohmic contacts.

25. The method of claim 22, wherein the electroabsorption material comprises one or more layers of graphene or graphene-based composite material.

26. An optical device, comprising:
semiconductor light source configured to generate output light,
wherein the semiconductor light source comprises a modulation structure comprising electroabsorption material, and
wherein the modulation structure is configured to modulate the output light via a bias-dependent absorption provided by the electroabsorption material.

27. The optical device of claim 26, wherein the electroabsorption material comprises graphene or graphene-based composite material.

28. The optical device of claim 26, wherein the semiconductor light source comprises a micro light-emitting diode (micro-LED).

29. The optical device of claim 26, wherein the semiconductor light source comprises a vertical external cavity surface emitting laser (VECSEL).

30. The optical device of claim 26, wherein the semiconductor light source comprises a photonic crestal surface emitting laser (PCSEL).
